(19) United States
(12) Patent Application Publication
(10) Pub. No.: US 2002/0043400 A1
(43) Pub. Date: Apr. 18, 2002

(54) Semiconductor device

(75) Inventor: Minoru Shinohara, Saku (JP)

Correspondence Address: MILES & STOCKBRIDGE PC, 1751 PINNACLE DRIVE, SUITE 500, MCLEAN, VA, 22102-3833, US

(73) Assignee: Hitachi, Ltd.

(21) Appl. No.: 09/923,402

(22) Filed: Aug. 8, 2001

(30) Foreign Application Priority Data
Aug. 31, 2000 (JP) 2000-264272

(51) Int. Cl. H01L 23/02; H05K 1/16

(52) U.S. Cl. 174/260; 257/684; 257/679

(57) ABSTRACT

A technique for attaining a large capacity of a memory card type semiconductor device is disclosed. A Cu pattern is formed centrally of a bending portion (BAL) on a flexible substrate and Cu patterns are formed at end portions of mounting areas (MAL, MAC) located on both sides of the bending portion. When the flexible substrate is bent along the bending portion (BAL), only film exposed portions present on both sides of the Cu pattern are bent with a small radius of curvature and the end portions of the mounting areas (MAL, MAC) and the vicinities thereof are kept flat.

### BACKGROUND OF THE INVENTION

The present invention relates to a semiconductor device. Particularly, the invention is concerned with a technique applicable effectively to a memory card type semiconductor device wherein a flexible substrate with electronic components such as memory chips mounted thereon is received within a case.

In Japanese Published Unexamined Patent Application No. Hei 5(1993)-13664 there is disclosed a multi-chip package wherein a TAB tape with plural semiconductor chips mounted thereon longitudinally is bent 180° to let the chips lap each other and in this state the TAB tape and the chips are sealed together with resin. In the bending portion of the TAB tape are formed two parallel slits by punching the tape so that the tape can be bent easily in the bending portion.

### SUMMARY OF THE INVENTION

The present inventor has developed a technique for attaining a large capacity of a COMPACT FLASH (a registered trademark of sun disc Co., U.S.A.) card (hereinafter referred to simply as “CF card”) based on “CFA (Compact Flash Association)” Standard.

In the CF card, a flexible substrate with plural memory chips mounted thereon is received within a case. For use of the CF card, a socket attached to a side face of the case is connected to an electronic device such as a digital camera, a hand-held PC, or an audio recorder.

For attaining a large memory capacity of the CF card it is required that a long flexible substrate with plural memory chips mounted thereon be folded in several layers and be received in this folded state into the case. However, when the flexible substrate is folded, a flexible film as the substrate material is bent arcuately and expands outwards at the folded portion, with the result that the external size becomes larger and hence the working efficiency in the work of accommodating the substrate into the case is deteriorated.

According to the drawings in the foregoing prior art (Japanese Published Unexamined Patent Application No. Hei 5(1993)-13664), the bending portion of the flexible film is perpendicular, but since the flexible film is continuous at end portions of the slits, there is a fear that the film may expands outwards at the end portions. Besides, since the rigidity of the flexible film is lower than that of a metal pattern for example and the film is actually bent at one central position of the bending portion, it is impossible to effectively decrease the outward expansion.

Further, when the flexible film is bent arcuately at the bending portion, an end of the arc extends up to a memory chip mounted area, so that an unnecessary bending stress is applied to soldered portions between the chips and the substrate and the connection reliability is deteriorated. In an effort to eliminate this problem, if chips are not disposed near the bending portion, i.e., at an end portion of the mounting area, an effective area of the mounting area substantially becomes smaller and the chip mounting density decreases, so that the attempt to increase the capacity of the CF card is impeded.

It is an object of the present invention to provide a technique for attaining a large capacity of a memory card type semiconductor device wherein a flexible substrate with electronic components mounted thereon is folded and received within a case.

It is another object of the present invention to provide a technique for improving the reliability of a memory card type semiconductor device wherein a flexible substrate with electronic components mounted thereon is folded and received within a case.

It is a further object of the present invention to provide a technique for improving an assembling work efficiency of a memory card type semiconductor device wherein a flexible substrate with electronic components mounted thereon is folded and received within a case.

The above and other objects and novel features of the present invention will become apparent from the following description and the accompanying drawings.

Out of constructions disclosed herein, a typical one will be outlined below.

In the semiconductor device of the present invention, plural electronic components are mounted on a flexible substrate constituted by a flexible film with wiring formed thereon and the flexible substrate is folded and received within a case. In this connection, reinforcing patterns higher in rigidity than the flexible film are formed in a bending portion of the flexible substrate and also at end portions of a pair of electronic components mounting areas located on both sides of the bending portion, permitting bending of only the flexible film portions present in gaps between the reinforcing pattern formed in the bending portion and the reinforcing patterns formed at end portions of the electronic components mounting areas.

According to this means, the flexible substrate is bent at two positions on both sides of the reinforcing pattern formed in the bending portion, so when the flexible substrate is folded, the radius of curvature of the bending portion becomes smaller and an effective area of each mounting area becomes larger. Besides, an external size accuracy of the thus-folded flexible substrate is improved.

According to the above means, an unnecessary bending stress is not imposed on the film of each components mounting area and flatness is ensured, whereby the connection reliability between the electronic components and the substrate is improved.

### BRIEF DESCRIPTION OF THE DRAWINGS

FIGS. 1(a) and 1(b) are perspective views showing appearances of a memory card type semiconductor device according to an embodiment of the present invention;

FIG. 2 is an exploded perspective view of the memory card type semiconductor device;

FIG. 3 is a side view showing a flexible substrate of the memory card type semiconductor device;

FIG. 4 is a plan view of the flexible substrate;

FIG. 5 is a plan view showing a layout of lines and reinforcing patterns formed on the flexible substrate;

FIGS. 6(a) and 6(b) are sectional views of bending portions extending in a long side direction of the flexible substrate and the vicinities thereof;

FIG. 7 is a sectional view of a part of a mounting area on the flexible substrate and a bending portion;

FIG. 8 is a perspective view showing a flexible substrate folding process;

FIG. 9 is a sectional view showing a flexible substrate folding process;

FIG. 10 is an enlarged sectional view of a principal portion shown in FIG. 9;

FIG. 11 is a perspective view showing a flexible substrate folding process;

FIG. 12 is a sectional view showing a flexible substrate folding process; and

FIG. 13 is an enlarged sectional view of a principal portion shown in FIG. 12.

### DETAILED DESCRIPTION OF A PREFERRED EMBODIMENT

An embodiment of the present invention will be described hereinunder with reference to the drawings. In all of the drawings for illustrating the embodiment, components having the same functions are identified by the same reference numerals and repeated explanations thereof will be omitted.

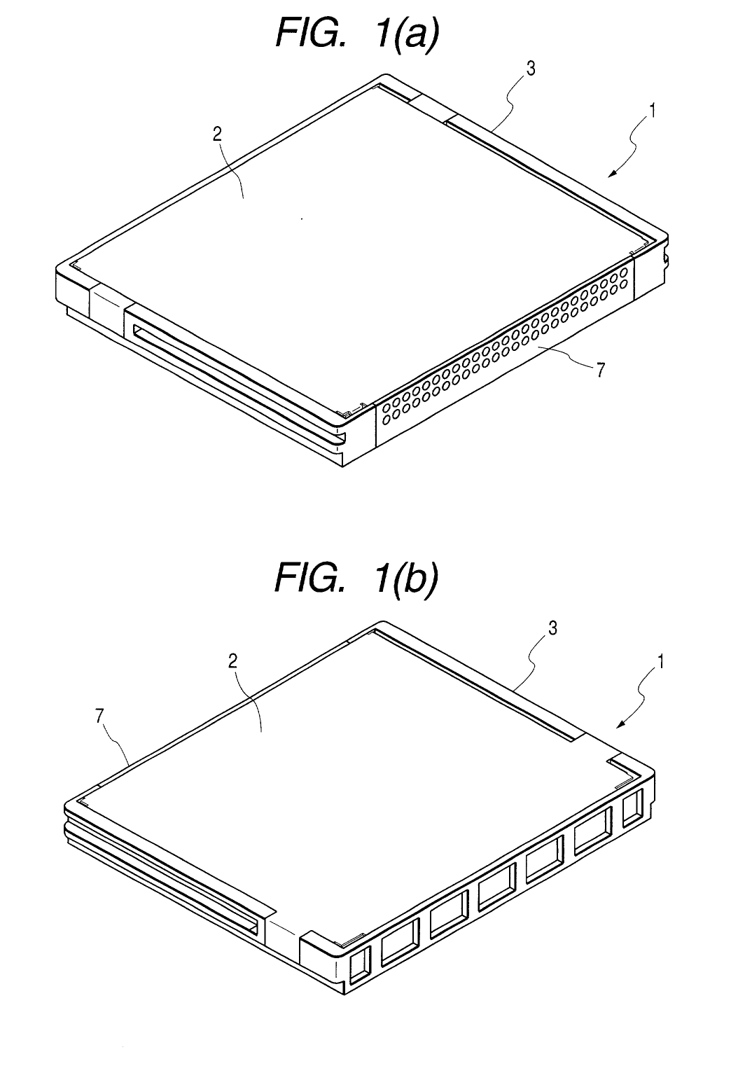

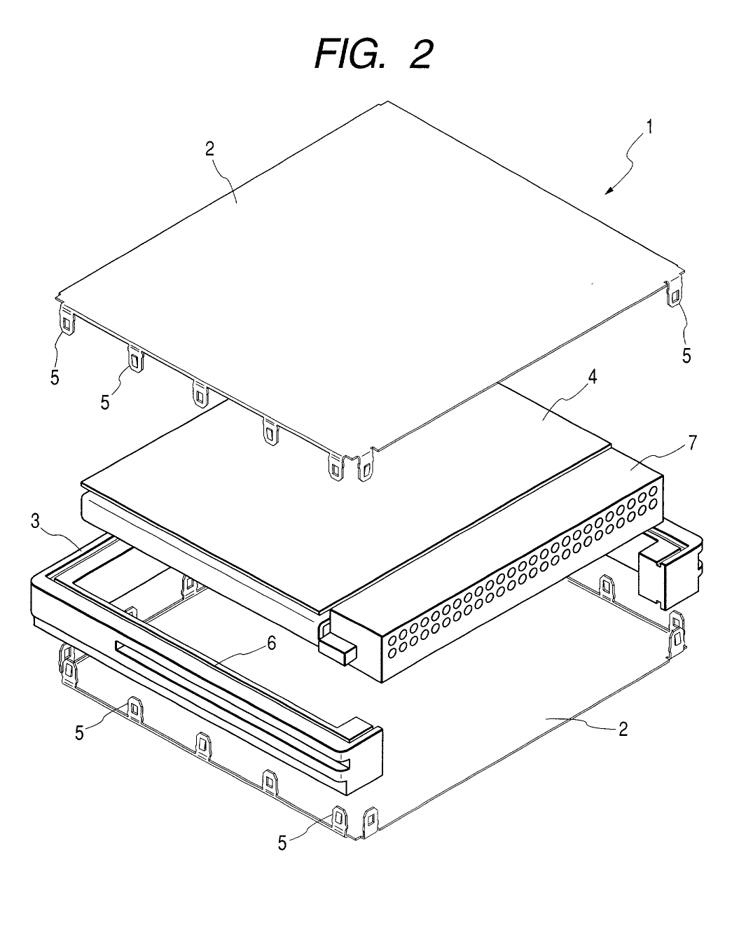

FIGS. 1(a) and 1(b) are perspective views showing appearances of a CF card type II according to this embodiment, in which FIG. 1(a) shows the CF card with a socket disposed on this side and FIG. 1(b) shows the same card with the side opposite to the socket disposed on this side. FIG. 2 is an exploded perspective view of the CF card.

As shown in the figures, the CF card, indicated at 1, comprises a case and a flexible substrate 4 received therein, the case comprising two panel cases 2 and one frame 3. A socket 7 for connecting the CF card 1 to any of various electronic devices such as a digital camera, a hand-held PC, and an audio recorder is attached to one side face of the flexible substrate 4. In the case of CF card type II, the case has external dimensions of 36.4 mm long, 42.8 mm wide, and 5 mm high. The socket 7 has 50 pins.

The two panel plates 2 are constituted by thin plates of stainless steel (SUS304) having the same shape. Plural pawl-like retaining portions 5 are formed on three outer sides of each panel plate 2 integrally with the same plate.

The frame 3 has a generally turned square U-shaped external form and is formed by monolithic molding of a resin superior in moldability such as PBT (polybutylene terephthalate) containing 15% glass fibers for example. Slots 6 for fitting therein of outer peripheral portions of the panel plates 2 are formed in both upper and lower surfaces of the frame 3. In the interior of the slots 6 are formed through holes (not shown) into which the retaining portions 5 of the panel plates 2 are inserted. By inserting the two panel plates 2 into the slots 6 from above and below the frame 3, the retaining portions 5 are fitted together within the through holes, whereby the panel plates 2 are fixed to the frame 3.

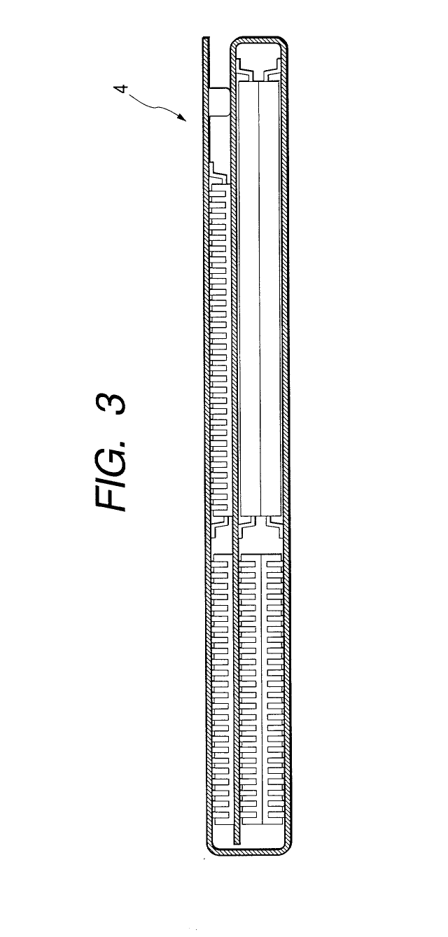

As shown in FIG. 3, the flexible substrate 4 received within the case of the CF card I is folded in three layers and plural electronic components which will be described later are mounted on a main surface (electronic components mounting surface) of the substrate.

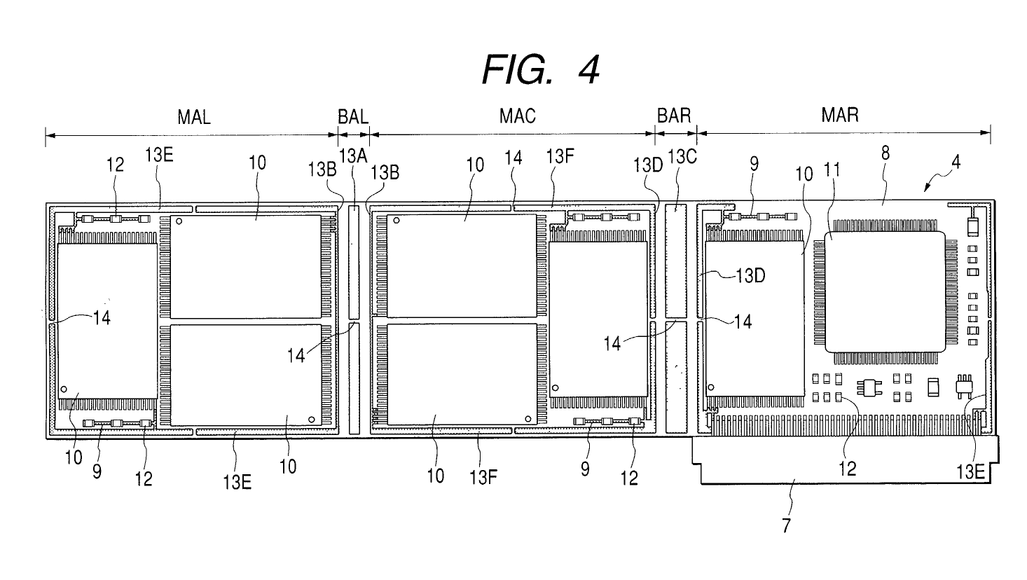

FIG. 4 is a plan view of the flexible substrate 4 in a developed state of the substrate main surface (electronic components mounting surface). The flexible substrate 4 comprises a flexible polyimide resin film 8 about 0.05 mm in thickness and Cu lines 9 about 0.02 mm in thickness formed on both surfaces of the film 8. The main surface of the flexible substrate 4 is partitioned to three electronic components mounting areas (MAL, MAC, MAR) and two bending portions (BAL, BAR) located among those mounting areas.

In each of the mounting areas (MAL) and (MAC), which are located on the left-hand side and the central side, respectively, in the figure there are mounted three 48-pin TSOPs (Thin Small Outline Packages) 10. In the mounting area (MAR), which is located on the right-hand side, there are mounted one 48-pin TSOP 10 and one 120-pin TQFP (Thin Quad Flat Package) 11. That is, on the main surface of the flexible substrate 4 are mounted a total of seven TSOPs 10 and one TQFP 11. Further, in each of the three mounting areas (MAL, MAC, MAR) are mounted passive components 12 such as resistors and chip capacitors. A socket 7 is soldered to one end of the right-hand mounting area (MAR). Such electronic components as TSOPs 10, TQFP 11, and passive components 12 are mounted on the main surface of the flexible substrate 4 using a known solder reflow method.

Centrally of the bending portion (BAL) located between the right-hand mounting area (MAL) and the central mounting area (MAC) is provided a band-like Cu pattern (reinforcing pattern) 13A which extends in the short-side direction (vertical direction in the figure) of the flexible substrate 4. Further, on both right and left sides of the Cu pattern 13A, i.e., at the right end of the mounting area (MAL) and at the left end of the mounting area (MAC), there are formed band-like Cu patterns 13B which extend in the short-side direction of the flexible substrate 4.

Likewise, centrally of the bending portion (BAR) located between the right-hand mounting area (MAR) and the central mounting area (MAC) is formed a band-like Cu pattern 13C which extends in the short-side direction of the flexible substrate 4. Further, on both sides of the Cu pattern 13C, i.e., at the left end of the mounting area (MAR) and at the right end of the mounting area (MAC), there are formed band-like Cu patterns 13D which extend in the short-side direction of the flexible substrate 4.

Cu patterns 13E are formed on an outer peripheral portion (two sides in the long-side direction of the flexible substrate 4 and one side in the short-side direction of the substrate) of the left-hand mounting area (MAL), and Cu patterns 13F are formed on an outer peripheral portion (two sides in the long-side direction of the flexible substrate 4) of the central mounting area (MAC). Further, a Cu pattern 13G is formed on part of an outer peripheral portion (one side in the short-side direction of the flexible substrate 4) of the right-hand mounting area (MAR).

Cutout portions 14 are formed nearly centrally of the Cu patterns 13A and 13C to 13G respectively. The cutout portions 14 are formed to relieve a thermal stress which is induced in the flexible substrate 4 due to a difference in thermal expansion coefficient between the Cu patterns 13A, 13C to 13G and the film 8 at the time of mounting electronic components on the main surface of the flexible substrate by the solder reflow method.

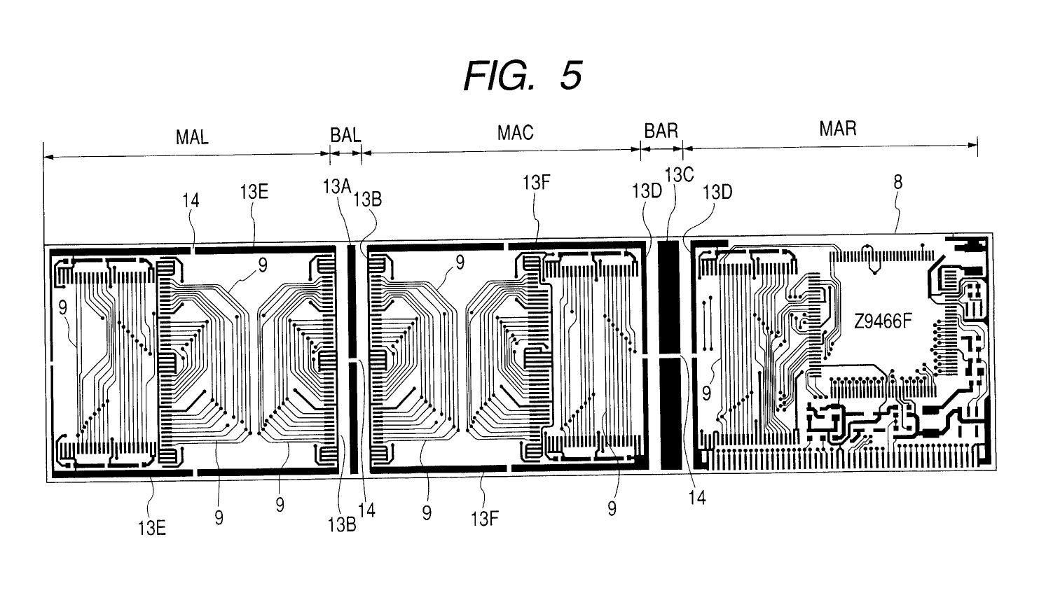

FIG. 5 shows a layout of the Cu patterns 13A to 13G and Cu lines 9 formed on the main surface of the flexible substrate 4. The Cu patterns 13A to 13G and Cu lines 9 are formed by etching Cu foil affixed to the film 8 and their surfaces, except a portion (electrodes to which terminals of electronic components and socket 7 are connected) of the Cu lines 9, are coated with a solder resist (insulating film) 15 (not shown).

As shown in the same figure, there is made layout so that the Cu lines 9 formed in the left-hand mounting area (MAL) and the Cu lines 9 formed in the central mounting area (MAC) are approximately axisymmetric with the central band-like Cu pattern 13A in the bending portion (BAL) as axis. Therefore, as shown in FIG. 4, the three TSOPs 10 mounted in the left-hand mounting area (MAL) and the three TSOPs 10 mounted in the central mounting area (MAC) are arranged so as to be approximately axisymmetric with the pattern 13A in the bending portion (BAL) as axis.

Further, there is made layout so that a portion of Cu lines 9 formed in the central mounting area (MAC) and a portion of Cu lines formed in the right-hand mounting area (MAR) are substantially axisymmetric with the band-like Cu pattern 13C at the center of the bending portion (BAR) as axis. Therefore, as shown in FIG. 4, the TSOP 10 mounted at the right end of the central mounting area (MAC) and the TSOP 10 mounted at the left end of the right-hand mounting area (MAR) are arranged so as to be substantially axisymmetric with the Cu pattern 13C in the bending portion (BAR) as axis.

Though not shown, on the back of the flexible substrate 4 are formed Cu lines 9 as power supply lines. Of the Cu patterns 13A to 13G formed on the main surface of the flexible substrate 4, the Cu patterns (13B, 13D to 13G) other than the Cu patterns (13A, 13C) formed centrally of the bending portions (BAL, BAR) are electrically connected to the ground lines (Cu lines 9) via a through hole (not shown) formed in the film 8. That is, the Cu patterns 13B and 13D to 13G constitute a part of the power supply lines and are connected electrically to power terminals of TSOPs 10, QFP 11 and passive components 12 through Cu lines 9 formed on the main surface side of the flexible substrate 4.

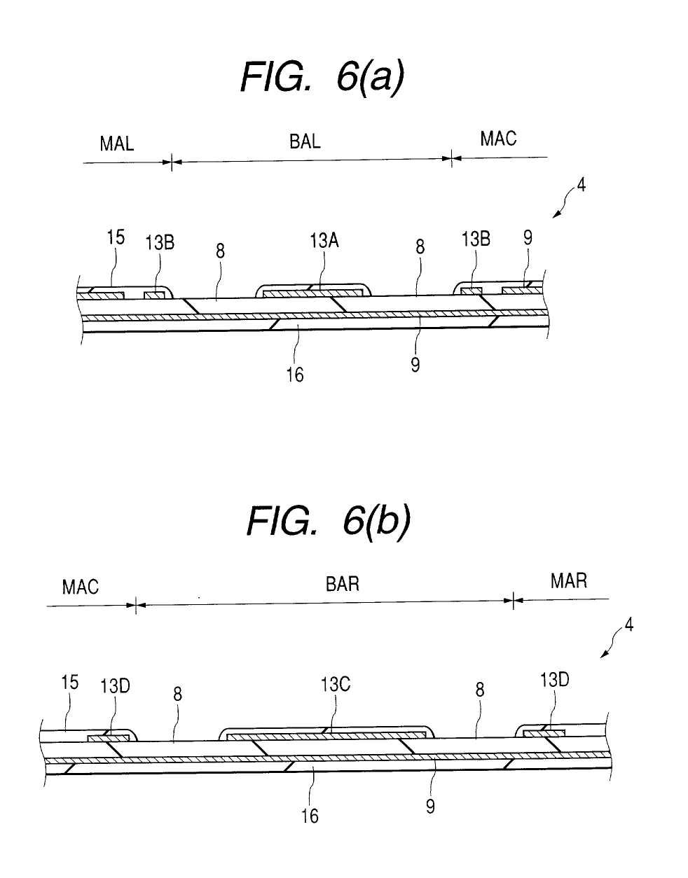

FIGS. 6(a) and 6(b) are sectional views of bending portions (BAL, BAR), respectively, extending in the long-side direction of the flexible substrate 4, as well as the vicinities thereof.

As shown in FIG. 6(a), a Cu pattern 13A is formed centrally of the bending portion (BAL) and Cu patterns 13B and Cu lines 9 are formed in the mounting areas (MAL, MAC) located on both sides of the bending portion (BAL). The surfaces of the Cu patterns 13A, 13B and the Cu lines 9 are covered with solder resist 15. Neither Cu line 9 nor solder resist 15 is formed in the areas (the two areas indicated with arrows in the figure) between the Cu pattern 13A and the Cu patters 13B formed on both sides thereof, but the surface of the film 8 is exposed in the areas.

As shown in FIG. 6(b), a Cu pattern 13C is formed centrally of the bending portion (BAR) and Cu patterns 13D and Cu lines 9 are formed in the mounting areas (MAC, MAR) located on both sides of the bent portion (BAR). The surfaces of the Cu patterns 13C, 13D and Cu lines 9 are covered with solder resist 15. In the areas (the two areas indicated with arrows in the figure) between the Cu pattern 13C and the Cu patterns 13D located on both sides thereof there is formed neither Cu line 9 nor solder resist 15, but the surface of the film 8 is exposed.

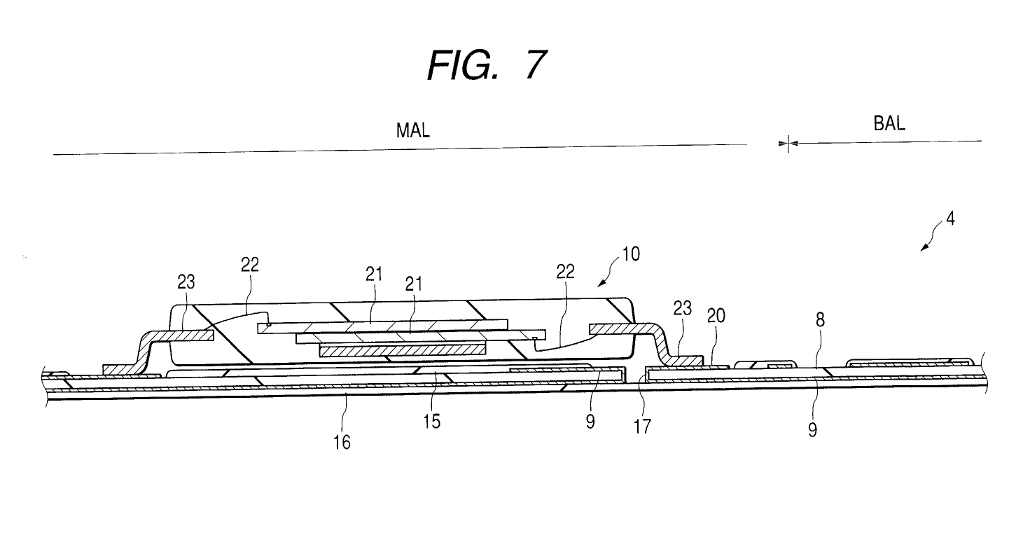

FIG. 7 is a sectional view of a part of the mounting area (MAL) and the bending portion (BAL) on the flexible substrate 4.

The Cu lines 9 on the main surface side of the flexible substrate 4 are coated with solder resist 15 except the surfaces of electrodes 20 as part of the Cu lines. On the other hand, the Cu lines (power lines, ground lines) 9 on the back side of the substrate are coated with cover coat (insulating film) 16. A portion of the Cu lines 9 on the main surface side and the Cu lines 9 on the back side are electrically connected together via a through hole 17 formed in the film 8.

Two memory chips 16 are sealed in a laminated state in each TSOP 10 mounted on the main surface of the flexible substrate 4. More specifically, each TSOP 10 has a DDP (Double Density Package) structure wherein two memory chips 21 are laminated and sealed in a single package. Each of the memory chips 21 is electrically connected to one end (inner lead portion) of a lead 23 via an Au wire 22. An opposite end (outer lead portion) of the lead 23 is soldered onto an electrode 20 on the flexible substrate 4.

In each of the memory chips 21 is formed a flash memory having a memory capacity of say 256 Mb (megabit). That is, each TSOP 10 with two memory chips 21 sealed therein has a memory capacity of 512 Mb=64 Mbyte. Since seven TSOPs 10 are mounted on the flexible substrate 4, the CF card 1 of this embodiment has a memory capacity of 64×7=448 Mbyte.

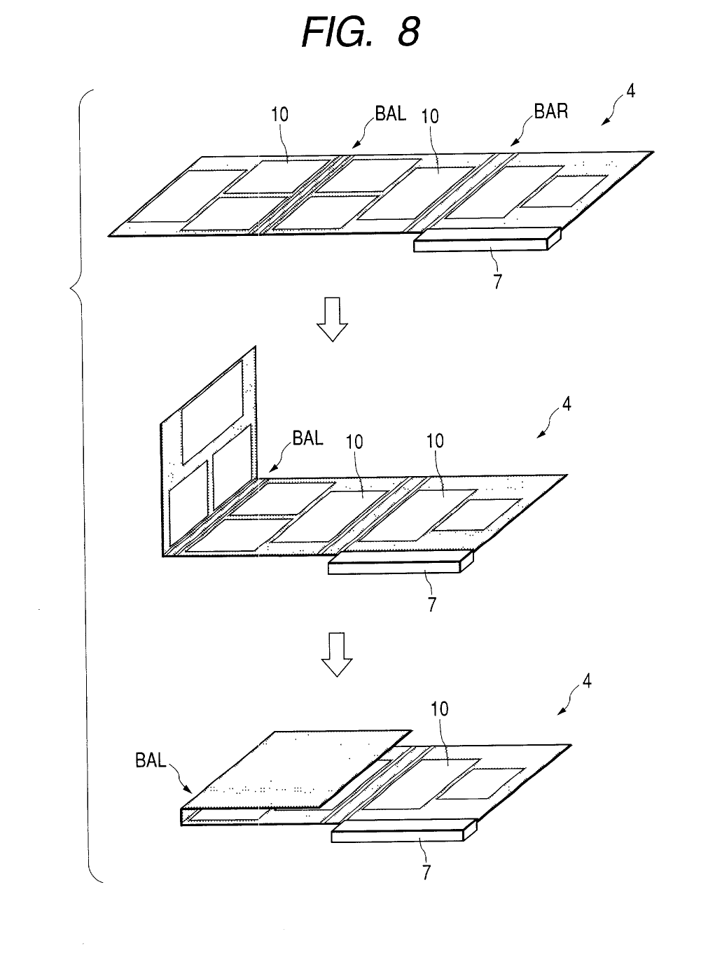

The flexible substrate 4 is folded in the following manner. First, as shown in FIG. 8, the flexible substrate 4 is bent 180° relative to the bending portion (BAL) so that the mounting areas (MAL, MAC) confront each other.

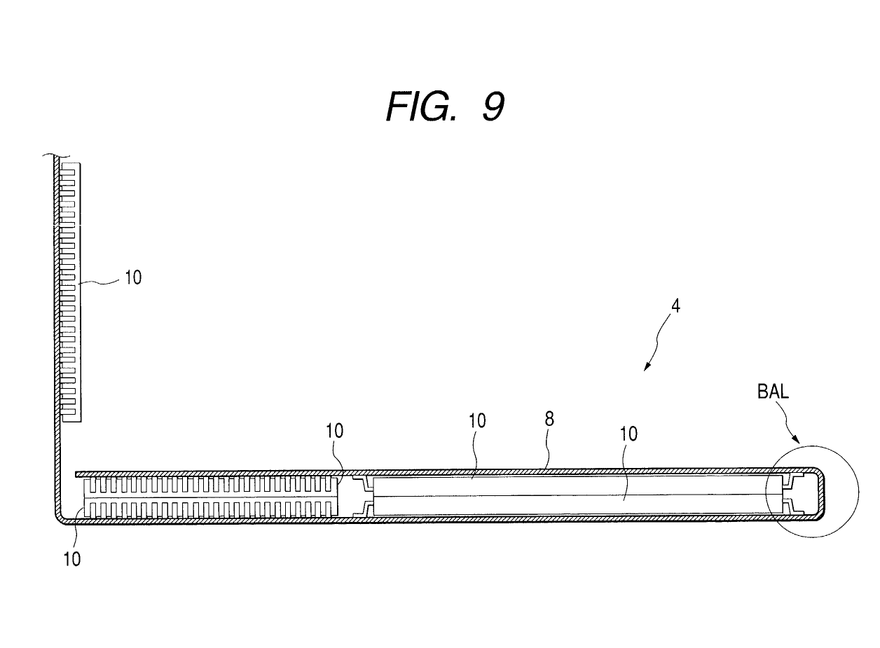

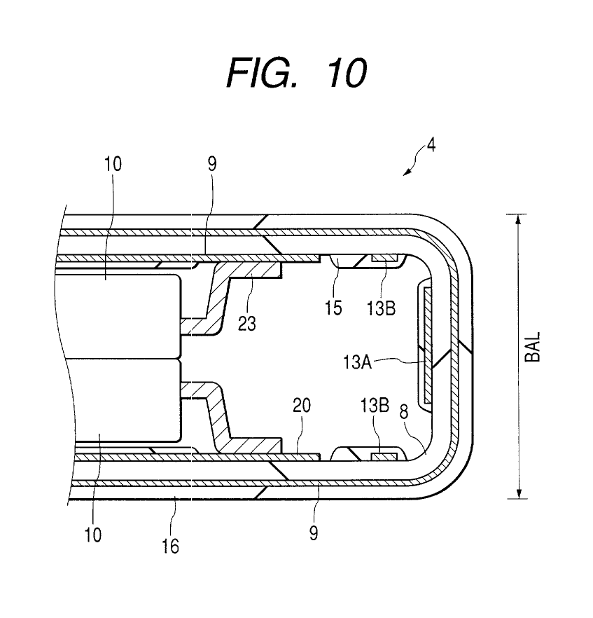

FIG. 9 is a partial sectional view of the flexible substrate 4, showing this folding state, and FIG. 10 is an enlarged sectional view of the bending portion (BAL) and the vicinity thereof.

As described above, the Cu pattern 13A is formed centrally of the bending portion (BAL) and the Cu patterns 13B are formed at end portions of the mounting areas (MAL, MAC). Therefore, when the flexible substrate 4 is bent along the bending portion (BAL), as shown in FIG. 10, only the film 8-exposed portions on both sides of the Cu pattern 13A are bent with a small radius of curvature, whereby the end portions of the mounting areas (MAL, MAC) and the vicinities thereof are kept flat.

Consequently, a bending stress is not imposed on the end portions of the mounting areas (MAL, MAC) and the vicinities thereof, so that even if electronic components are disposed near the end portions of the mounting areas (MAL, MAC), the connection reliability between the electronic components and the flexible substrate 4 is ensured. As a result, an effective area of the mounting areas (MAL, MAC) is substantially enlarged and a high-density mounting of electronic components can be attained by the mounting areas (MAL, MAC).

As noted earlier, the three TSOPs 10 mounted on the mounting area (MAL) and the three TSOPs 10 mounted on the mounting area (MAC) are arranged so as to be approximately axisymmetric with the Cu pattern 13A in the bending portion (BAL) as axis. Therefore, when the flexible substrate 4 is bent along the bending portion (BAL), as shown in FIG. 9, the TSOPs 10 in the mounting areas (MAL, MAC) are folded so that their molded resins are superimposed one on the other, so there is no fear of short-circuit of the leads 23.

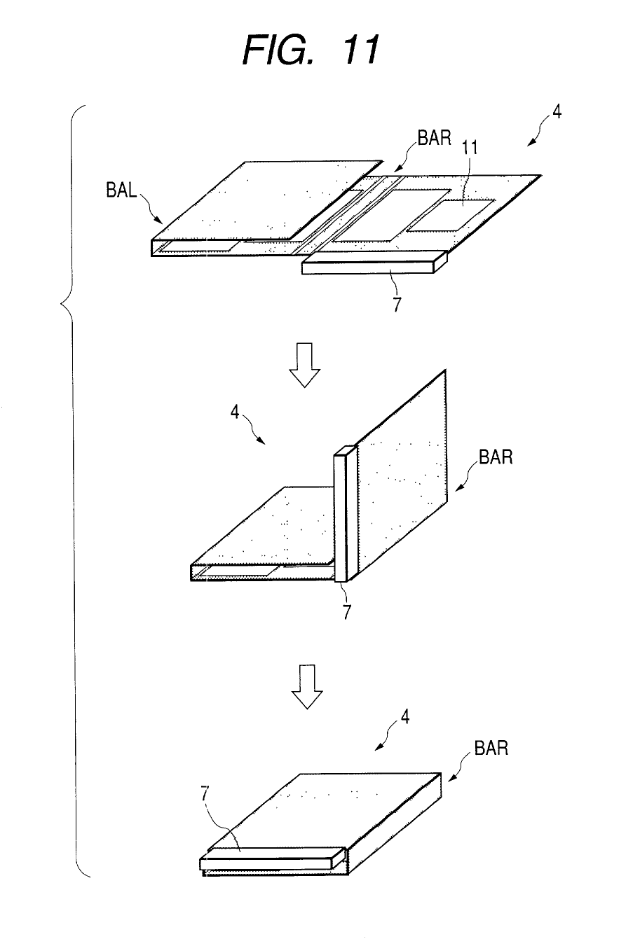

Next, as shown in FIG. 11, the flexible substrate 4 is bent 180° along the other bending portion (BAR) so that the back of the mounting area (MAL) and the mounting area (MAR) confront each other. In this way the flexible substrate 4 is folded in three layers.

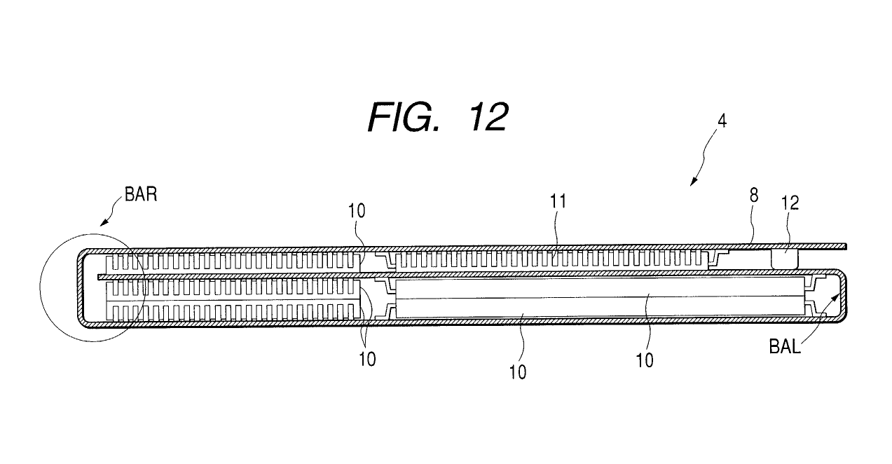

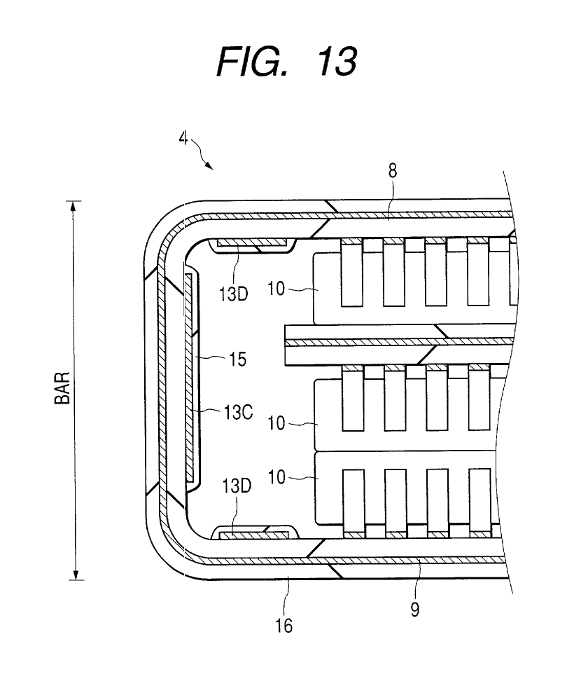

FIG. 12 is a partial sectional view of the flexible substrate 4, showing this folding state, and FIG. 13 is an enlarged sectional view of the bending portion and the vicinity thereof.

As mentioned previously, a Cu pattern 13C is formed centrally of the bending portion (BAR) and Cu patterns 13D are formed at end portions of the mounting areas (MAR, MAC). Therefore, when the flexible substrate 4 is bent along the bending portion (BAR), as shown in FIG. 13, only the film 8-exposed portions present on both sides of the Cu pattern 13 are bent with a small radius of curvature, whereby the end portions of the mounting areas (MAR, MAC) and the vicinities thereof are kept flat.

Consequently, a bending stress is not imposed on the end portions of the mounting areas (MAR, MAC) and the vicinities thereof, so even if electronic components are disposed near the end portions of the mounting areas (MAR, MAC), it is possible to ensure the connection reliability between the electronic components and the flexible substrate 4. That is, an effective area of the mounting areas (MAR, MAC) is substantially enlarged and therefore it is possible to mount a larger number of electronic components on the mounting areas (MAR, MAC).

Thereafter, the flexible substrate 4 thus folded in three layers is accommodated into the case to complete the CF card 1 shown in FIG. 1.

The flexible substrate 4 folded in three layers is bent nearly rectilinearly at two bending portions (BAL, BAR). In other words, at the bending portions (BAL, BAR) the flexible substrate 4 does not expand outwards. Besides, the thickness of the flexible substrate 4 is defined by the width of the Cu patterns 13A and 13C formed in the bending portions (BAL, BAR). Consequently, external dimensions of the flexible substrate 4 when folded are constant, thus permitting the substrate to be easily accommodated into the case, whereby the efficiency of the CF card 1 assembling work is improved.

In the CF card 1 of this embodiment, moreover, the layout of Cu lines 9 and Cu patterns 13B, 13D to 13G formed in the electronic components mounting areas (MAL, MAC, MAR) or the arrangement of electronic components is made so as to be approximately axisymmetric with the bending portions (BAL, BAR) as axes. Consequently, a bending stress imposed on the flexible substrate 4 is dispersed almost uniformly on both sides of each bending portion (BAL, BAR), thus permitting bending with a high dimensional accuracy.

Further, in the CF card 1 of this embodiment, cutout portions 14 are formed in the Cu patterns 13A and 13C to 13G on the flexible substrate 4 to relieve a thermal stress which is induced in the flexible substrate at the time of reflow of solder due to a difference in thermal expansion coefficient between the Cu patterns 13A, 13C to 13G and the film 8. Consequently, it becomes possible to effect bending with a higher dimensional accuracy.

In the CF card 1 of this embodiment, a portion of the Cu patterns 13A to 13G formed on the main surface of the flexible substrate 4 is utilized as power lines, whereby the wiring of power lines becomes easier and the wiring length from the power supply section up to the electronic components can be shortened. Consequently, an inductance component in the power lines which causes a power noise can be diminished.

Although the invention accomplished by the present inventor has been described above concretely by way of an embodiment thereof, it goes without saying that the invention is not limited to the above embodiment, but that various modifications may be made within the scope not departing from the gist of the invention.

Although in the above embodiment the flexible substrate is folded in three layers, the invention is also applicable to the case where the flexible substrate is folded in two layers.

Although in the above embodiment the reinforcing patterns are formed using the same material as the material of wiring lines, they may be formed using a different material.

Although the flexible substrate used in the above embodiment is of a two-layer interconnection structure, there also may be used a flexible substrate of a multilayer interconnection structure having three or more layers as inner wiring layers of the flexible film.

Although the flexible substrate used in the above embodiment has electronic components mounted on only one side thereof, there also may be used flexible substrate having electronic components mounted on both sides thereof. Although in the above embodiment the present invention is applied to CF card type II, the invention is also applicable to CF card type I having a case thickness of 3.3 mm. As the method for mounting memory and control chips onto the flexible substrate there also may be adopted a TCP (Tape Carrier Package) method.

As memory chips, not only flash memory-formed chips, but also DRAM- or SRAM-formed chips may be used. Thus, the present invention is widely applicable not only to the CF card but also to various memory card type semiconductor devices wherein a flexible substrate with electronic components mounted thereon is folded and accommodated into a case.

A brief description will be given below about typical effects attained by the present invention.

According to the present invention, since electronic components can be mounted in high density on the flexible substrate, it is possible to attain a large capacity of the memory card type semiconductor device.

According to the present invention, since the connection reliability between the flexible substrate and the electronic components mounted thereon is improved, the reliability of the memory card type semiconductor device is improved.

According to the present invention, since the dimensional accuracy of the flexible substrate in a folded state is improved, the efficiency of the work for assembling the memory card type semiconductor device is improved.

According to the present invention, since it is possible to diminish the inductance of power lines formed on the flexible substrate, the operation reliability of the memory card type semiconductor device is improved.

According to the present invention, since a bending stress imposed on the flexible substrate is dispersed almost uniformly on both sides of each bending portion, it is possible to effect bending with a high dimensional accuracy.

What is claimed is:

1. A semiconductor device in which a plurality of electronic components are mounted on a flexible substrate constituted by a flexible film with wiring formed thereon and the flexible substrate is folded and received within a case,
wherein a reinforcing pattern is formed in a bending portion of the flexible substrate and reinforcing patterns are also formed at end portions of a pair of electronic components mounting areas, respectively, located on both sides of the bending portion, and portions of the flexible film present in gaps between the reinforcing pattern formed in the bending portion and the reinforcing patterns formed at end portions of the electronic components mounting areas are bent, whereby the flexible substrate is folded.

2. A semiconductor device according to claim 1, wherein the electronic components mounted on one of the paired electronic components mounting areas and the electronic components mounted on the other electronic components mounting area are arranged so as to be approximately axisymmetric with the bending portion as axis.

3. A semiconductor device according to claim 1, wherein wiring formed on one of the paired electronic components mounting areas and wiring formed on the other electronic components mounting area are arranged so as to be approximately axisymmetric with the bending portion as axis.

4. A semiconductor device according to claim 1, wherein the reinforcing patterns formed at end portions of the electronic components mounting areas extend so as to surround the electronic components mounting areas.

5. A semiconductor device according to claim 1 or claim 4, wherein cutout portions are formed in part of the reinforcing patterns.

6. A semiconductor device according to claim 1, wherein the reinforcing patterns are formed using the same material as the material of the wiring.

7. A semiconductor device according to claim 6, wherein the reinforcing patterns constitute a part of a power wiring.

8. A semiconductor device according to claim 1, wherein the electronic components includes a memory chip.

9. A semiconductor device according to claim 8, wherein the memory chip is sealed in a TSOP.

10. A semiconductor device according to claim 1, wherein the wiring is formed on both sides of the flexible film.

11. A semiconductor device according to claim 10, wherein the bending portion of the flexible film is formed with wiring on only one side thereof.

12. A semiconductor device according to claim 11, wherein the surface of the wiring and the surfaces of the reinforcing patterns are coated with a solder resist.

13. A semiconductor device according to claim 12, wherein the portions of the flexible film present in the gaps between reinforcing pattern formed in the bending portion and the reinforcing patterns formed at end portions of the electronic components mounting areas are coated with the solder resist on only one sides thereof.

14. A semiconductor device according to claim 1, wherein the flexible substrate is folded in three layers.

15. A semiconductor device according to claim 14,
wherein the flexible substrate has three electronic components mounting areas and two bending portions positioned among the three electronic components mounting areas,
wherein, out of the three electronic components mounting areas, in one of two electronic components mounting areas except a central electronic components mounting area, a socket is attached to a longitudinal side face of the flexible substrate,
wherein, in the electronic components mounting area with the socket attached thereto, passive components are mounted in the vicinity of the socket; and
wherein the flexible substrate is folded so that the electronic components mounting area with the socket attached thereto confronts the back of the other electronic components mounting area.

16. A semiconductor device in which a plurality of electronic components are mounted on a flexible substrate constituted by a flexible film with wiring formed thereon and the flexible substrate is folded and received within a case,
wherein a reinforcing pattern is formed in a bending portion of the flexible substrate and reinforcing patterns are also formed at end portions of a pair of electronic components mounting areas, respectively, located on both sides of the bending portion, and portions of the flexible film present in gaps between the reinforcing pattern formed in the bending portion and the reinforcing portions formed at end portions of the electronic components mounting areas are bent at two positions on both sides of the reinforcing pattern formed in the bending portion, whereby the flexible substrate is folded.
